(19) United States
(12) Patent Application Publication
(10) Pub. No.: US 2018/0286690 A1
(43) Pub. Date: Oct. 4, 2018

(54) METHOD OF PROCESSING WORKPIECE

(71) Applicant: DISCO CORPORATION, Tokyo (JP)

(72) Inventor: Kenji Takenouchi, Tokyo (JP)

(21) Appl. No.: 15/937,441

(22) Filed: Mar. 27, 2018

(30) Foreign Application Priority Data
Apr. 4, 2017 (JP) 2017-074251

(51) Int. Cl. H01L 21/304; H01L 21/683; H01L 21/311; H01L 21/67

(52) U.S. Cl. CPC H01L 21/3043; H01L 21/6833; H01L 21/67069; H01L 21/31144; H01L 21/6836; H01L 21/31138

(57) ABSTRACT

A plate-shaped workpiece includes a layered body containing metal which is formed in superposed relation to projected dicing lines. The workpiece is processed by holding a layered body side of the workpiece on a first holding table, thereafter, dry etching the workpiece through a mask disposed in areas that are exclusive of the projected dicing lines to form etched grooves along the projected dicing lines in a manner to leave the layered body unremoved, thereafter, holding the layered body side or an opposite side on a second holding table, and thereafter, cutting bottoms of the etched grooves with a cutting blade to sever the workpiece and the layered body along the projected dicing lines. The bottoms of the etched grooves are cut while supplying a cutting fluid containing an organic acid and an oxidizing agent to the workpiece.

### BACKGROUND OF THE INVENTION

### Field of the Invention

The present invention relates to a method of processing a plate-shaped workpiece that includes a layered body containing metal which is formed in superposed relation to projected dicing lines.

### Description of the Related Art

Electronic equipment, typically mobile phones and personal computers, incorporates, as indispensable components, device chips that have devices such as electronic circuits, etc. thereon. A device chip is manufactured by demarcating the face side of a wafer made of a semiconductor material such as silicon or the like into a plurality of areas with a plurality of projected dicing lines also known as streets, forming devices in the respective areas, and then dividing the wafer into device chips corresponding to the devices along the projected dicing lines.

In recent years, evaluation elements referred to as TEG (Test Element Group) for evaluating electric properties of devices are often formed on projected dicing lines on wafers as described above (see, for example, Japanese Patent Laid-open No. Hei 6-349926 and Japanese Patent Laid-open No. 2005-21940). The TEG on the projected dicing lines on a wafer makes it possible to maximize the number of device chips that can be fabricated from the wafer. Once the TEG has carried out evaluations and has been made redundant, it can be removed at the same time that the wafer is severed into device chips.

### SUMMARY OF THE INVENTION

When layered bodies containing metal such as TEG are cut and removed by a cutting blade which is made of a binder with abrasive grains dispersed therein, the metal contained in the layered bodies is elongated, tending to give rise to protrusions called “burrs” due to contact with the cutting blade. If the cutting blade processes the wafer at an increased rate, then it generates more heat that is liable to produce larger burrs. Therefore, according to the processing method using the cutting blade, it is necessary to reduce the processing rate so as not to lower the quality of the processing of the wafer.

It is therefore an object of the present invention to provide a method of processing a plate-shaped workpiece that includes a layered body containing metal which is formed in superposed relation to projected dicing lines, at an increased rate while keeping the quality of the processing of the workpiece.

In accordance with an aspect of the present invention, there is provided a method of processing a plate-shaped workpiece that includes a layered body containing metal which is formed in superposed relation to projected dicing lines, including the steps of holding a layered body side of the workpiece on a first holding table, thereafter, performing dry etching on the workpiece through a mask disposed in areas that are exclusive of the projected dicing lines thereby to form etched grooves in the workpiece along the projected dicing lines in a manner to leave the layered body unremoved, thereafter, holding the layered body side of the workpiece or a side of the workpiece which is opposite the layered body side thereof on a second holding table, and thereafter, cutting bottoms of the etched grooves with a cutting blade to sever the workpiece and the layered body along the projected dicing lines, in which the step of cutting the bottoms of the etched grooves includes the step of cutting the bottoms of the etched grooves while supplying a cutting fluid containing an organic acid and an oxidizing agent to the workpiece.

In the above aspect of the present invention, the cutting blade should preferably have a thickness smaller than the width of the etched grooves.

According to the method in accordance with the aspect of the present invention, the cutting fluid which contains an organic acid and an oxidizing agent is supplied to the cutting blade and the workpiece in severing the layered body containing metal with the cutting blade. The organic acid and the oxidizing agent are effective to modify the metal contained in the layered body, thereby lowering the ductility of the metal while the cutting blade is severing the layered body. The metal is thus prevented from forming burrs even when the workpiece is processed at an increased rate. In other words, the rate at which the workpiece is processed can be increased while keeping the quality of the processing of the workpiece.

According to the method in accordance with the aspect of the present invention, inasmuch as dry etching is performed on the workpiece through the mask provided in the areas exclusive of the projected dicing lines, processing the workpiece at once along all the projected dicing lines to form the etched grooves therein, the time required to process the workpiece per projected dicing line is shortened while keeping the quality of the processing of the workpiece, especially if the number of the projected dicing lines on the workpiece is large. In other words, the rate at which the workpiece is processed can be increased while keeping the quality of the processing of the workpiece.

The above and other objects, features and advantages of the present invention and the manner of realizing them will become more apparent, and the invention itself will best be understood from a study of the following description and appended claims with reference to the attached drawings showing preferred embodiment of the invention.

### BRIEF DESCRIPTION OF THE DRAWINGS

FIG. 1A is a perspective view schematically showing a workpiece by way of example;

FIG. 1B is a perspective view schematically showing the workpiece to which a dicing tape, etc. is stuck;

FIG. 2A is a fragmentary side elevational view, partly in cross section, illustrative of a mask forming step of a workpiece processing method according to an embodiment of the present invention;

FIG. 2B is a sectional elevational view schematically showing a dry etching apparatus;

FIG. 3A is a fragmentary side elevational view, partly in cross section, schematically showing the workpiece with etched grooves formed therein in a dry etching step of the workpiece processing method;

FIG. 3B is a side elevational view, partly in cross section, illustrative of a second holding step of the workpiece processing method;

FIG. 4 is a fragmentary side elevational view, partly in cross section, illustrative of a cutting step of the workpiece processing method; and

FIG. 5 is a side elevational view of a nozzle for supplying a cutting fluid according to another mode of the present invention.

### DETAILED DESCRIPTION OF THE PREFERRED EMBODIMENT

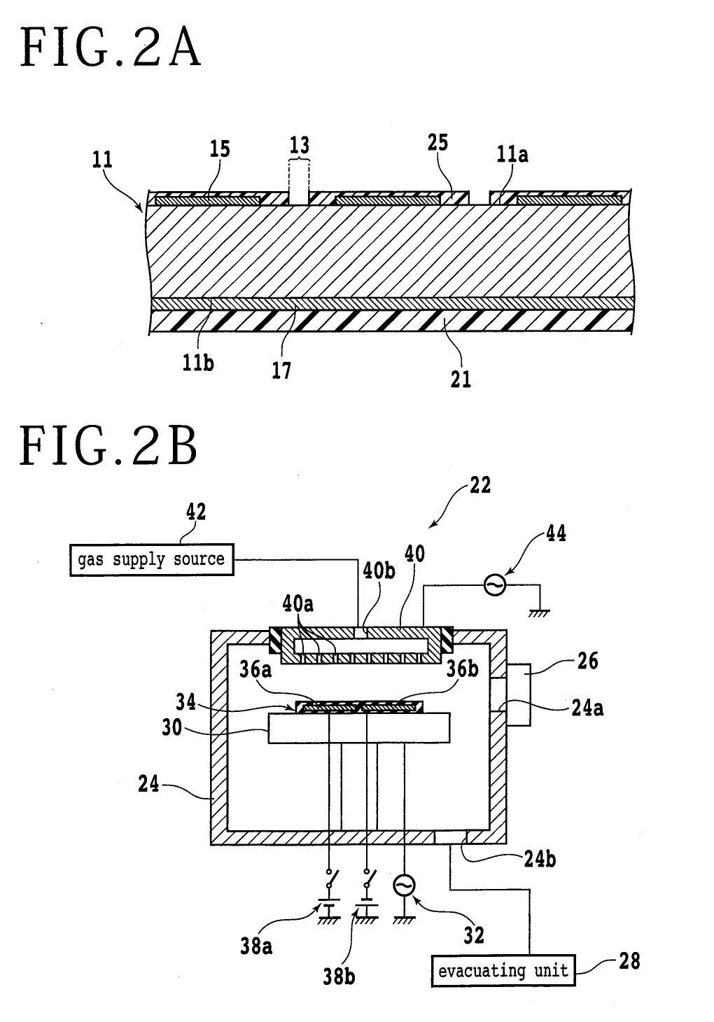

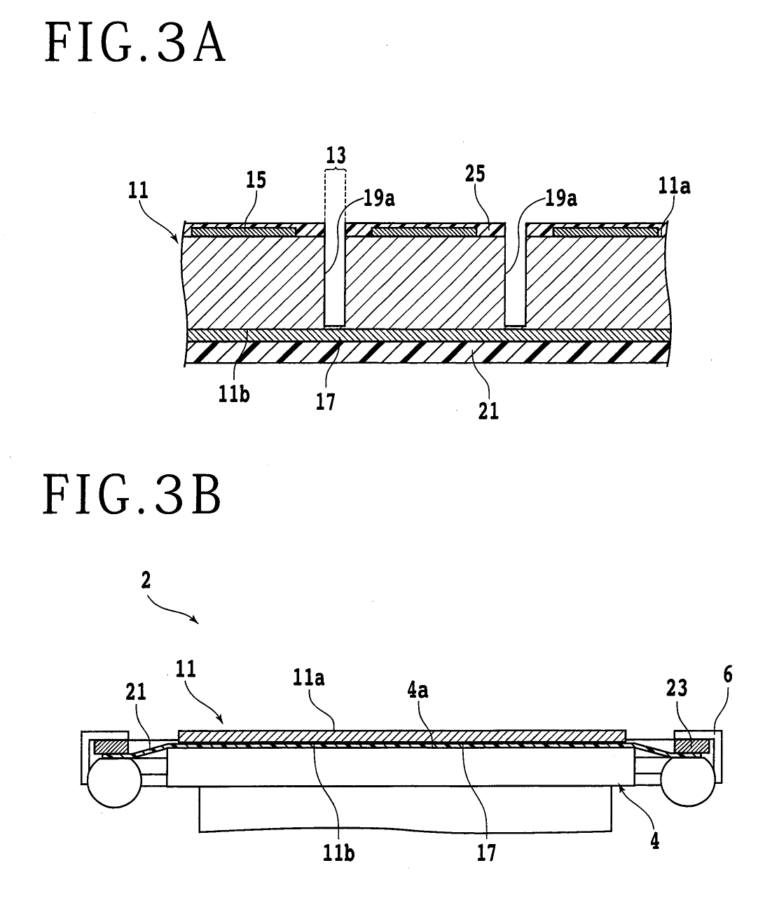

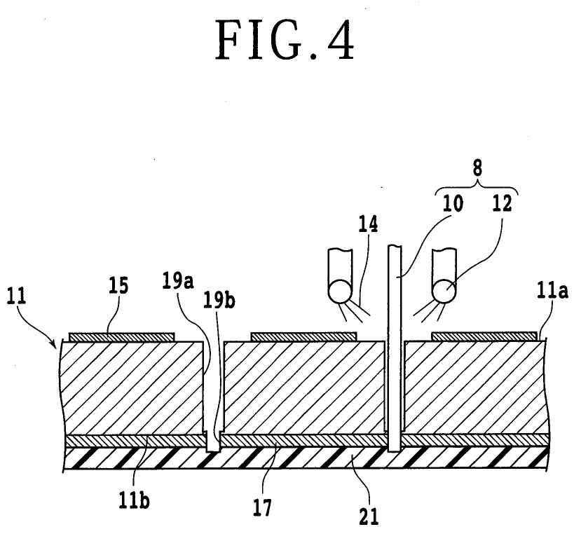

A method of processing a workpiece according to an embodiment of the present invention will be described below with reference to the accompanying drawings. The method of processing a workpiece according to the present embodiment, also referred to as “workpiece processing method,” is a method of processing a plate-shaped workpiece that includes a layered body containing metal which is formed in superposed relation to projected dicing lines, and includes a mask forming step (see FIG. 2A), a first holding step (see FIG. 2B), a dry etching step (see FIG. 3A), a second holding step (see FIG. 3B), and a cutting step (see FIG. 4).

In the mask forming step, a mask is formed on a side of the workpiece that is opposite the layered bodies. The mask is formed in areas that are exclusive of the projected dicing lines. In the first holding step, the side of the workpiece on which the layered body is formed is held on an electrostatic chuck (first holding table) of a dry etching apparatus such that the mask is exposed. In the dry etching step, dry etching is performed on the workpiece through the mask, forming etched grooves in the workpiece along the projected dicing lines in a manner to leave the layered body unremoved. In the second holding step, the side of the workpiece on which the layered body is formed is held on a chuck table (second holding table) of a cutting apparatus. In the cutting step, the bottoms of the etched grooves are cut by a cutting blade while a cutting fluid containing an organic acid and an oxidizing agent is being supplied to the workpiece, thus severing the workpiece and the layered body along the projected dicing lines. The workpiece processing method according to the present embodiment will be described in detail below.

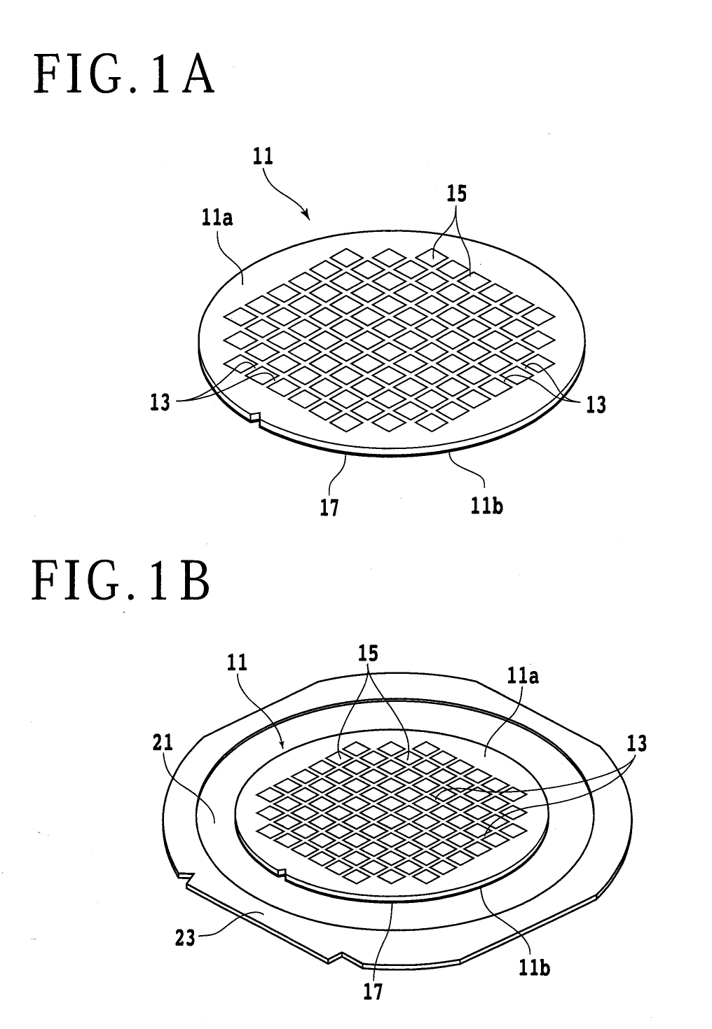

FIG. 1A is a perspective view schematically showing a workpiece 11 by way of example, which is to be processed by the workpiece processing method according to the present embodiment. As shown in FIG. 1A, the workpiece 11 includes a disk-shaped wafer made of a semiconductor material such as silicon (Si) or the like, and a face side 11a thereof is divided into a central device area and an outer peripheral marginal area surrounding the central device area.

The central device area is further demarcated into a plurality of areas by a grid of projected dicing lines or streets 13, with devices 15 such as an ICs (Integrated Circuits) or the like being formed in the respective areas. A layered body 17 that contains metal is provided on a reverse side 11b of the workpiece 11. The layered body 17 includes a multi-layer metal film of titanium (Ti), nickel (Ni), gold (Au), etc., having a thickness of approximately several μm and functioning as an electrode or the like. The layered body 17 is formed also in areas that are superposed on the projected dicing lines 13.

According to the present embodiment, the workpiece 11 is illustrated as including a disk-shaped wafer made of a semiconductor such as silicon or the like. However, the workpiece 11 is not limited to particular materials, shapes, structures, sizes, etc. Similarly, the devices 15 and the layered body 17 are not limited to particular kinds, quantities, shapes, structures, sizes, layouts, etc. For example, a packaged substrate where a layered body 17 functioning as an electrode is formed along projected dicing lines 13 may be used as the workpiece 11.

FIG. 1B is a perspective view schematically showing the workpiece 11 to which a dicing tape 21, etc. is stuck. As shown in FIG. 1B, before the workpiece processing method according to the present embodiment is carried out, the dicing tape 21, which is larger in diameter than the workpiece 11, is stuck to the reverse side 11b, i.e., the layered body 17, of the workpiece 11. An annular frame 23 is fixed to an outer peripheral portion of the dicing tape 21.

The workpiece 11 is thus supported on the annular frame 23 by the dicing tape 21. Though an example in which the workpiece 11 supported on the annular frame 23 by the dicing tape 21 is processed will be described below in the present embodiment, the workpiece 11 may be processed without the dicing tape 21 and the frame 23 being used.

In the workpiece processing method according to the present embodiment, the mask forming step is carried out to form a mask for dry etching in covering relation to the face side 11a of the workpiece 11 which opposites the layered body 17. FIG. 2A is a fragmentary side elevational view, partly in cross section, illustrative of the mask forming step, showing a mask 25 formed on the face side 11a of the workpiece 11.

The mask 25 is formed by a process such as photolithography or the like, and has at least a certain degree of resistance against subsequent dry etching. As shown in FIG. 2A, the mask 25 is formed in order to expose the projected dicing lines 13. In other words, the mask 25 is provided in areas exclusive of the projected dicing lines 13.

The mask forming step is followed by the first holding step to hold the workpiece 11 on an electrostatic chuck (first holding table) of a dry etching apparatus (plasma etching apparatus). FIG. 2B is a sectional elevational view schematically showing a dry etching apparatus (plasma etching apparatus) 22. The dry etching apparatus 22 includes a vacuum chamber 24 having a processing space defined therein. The vacuum chamber 24 includes a side wall having an opening 24a defined therein through which the workpiece 11 can be loaded into and out of the processing space in the vacuum chamber 24.

A gate 26 is provided outside of the opening 24a for selectively opening and closing the opening 24a. The gate 26 is connected to an opening/closing mechanism, not shown, which selectively opens and closes the gate 26. When the gate 26 is opened to expose the opening 24a, the workpiece 11 can be loaded through the opening 24a into the processing space in the vacuum chamber 24 or out of the processing space in the vacuum chamber 24.

The vacuum chamber 24 includes a bottom wall having an evacuating port 24b defined therein that is connected to an evacuating unit 28 such as a vacuum pump or the like. A lower electrode 30 is disposed in the processing space in the vacuum chamber 24. The lower electrode 30 is of a disk shape and made of an electrically conductive material, and is electrically connected to a high-frequency power supply 32 disposed outside of the vacuum chamber 24.

An electrostatic chuck 34 is disposed on an upper surface of the lower electrode 30. The electrostatic chuck 34 has a plurality of electrodes 36a and 36b that are insulated from each other, for example. The electrostatic chuck 34 attracts and holds the workpiece 11 under electric forces generated between the electrodes 36a and 36b and the workpiece 11. The electrostatic chuck 34 according to the present embodiment is arranged such that the electrode 36a can be connected to the positive terminal of a direct current (DC) power supply 38a whereas the electrode 36b can be connected to the negative terminal of a DC power supply 38b.

An upper electrode 40 that is of a disk shape and made of an electrically conductive material is mounted on a ceiling wall of the vacuum chamber 24 with an insulator interposed therebetween. The upper electrode 40 has a plurality of gas ejection holes 40a defined in a lower surface thereof that are connected to a gas supply source 42 through a gas supply hole 40b defined in an upper surface of the upper electrode 40. Therefore, the gas supply source 42 can supply a material gas for dry etching through the gas supply hole 40b and the gas ejection holes 40a to the processing space in the vacuum chamber 24. The upper electrode 40 is electrically connected to a high-frequency power supply 44 disposed outside of the vacuum chamber 24.

In the first holding step, the opening/closing mechanism lowers the gate 26, exposing the opening 24a. Then, the workpiece 11 is loaded through the exposed opening 24a into the processing space in the vacuum chamber 24, and placed on the electronic chuck 34. Specifically, the dicing tape 21 that sticks to the reverse side 11b, i.e., the layered body 17, of the workpiece 11 is held in contact with the upper surface of the electrostatic chuck 34. Thereafter, the electrostatic chuck 34 is energized to attract and hold the workpiece 11 thereon while the mask 25 on the face side 11a thereof is exposed upwardly.

After the first holding step, the dry etching step is carried out to perform dry etching (plasma etching) on the workpiece 11 through the mask 25 to form etched grooves in the workpiece 11 along the projected dicing lines 13 in a manner to leave the layered body 17 unremoved. The dry etching step is performed also using the dry etching apparatus 22.

Specifically, the opening/closing mechanism lifts the gate 26, closing the processing space in the vacuum chamber 24. Then, the evacuating unit 28 is actuated to depressurize the processing space. While the material gas for dry etching is being supplied from the gas supply source 42 at a predetermined flow rate, the high-frequency power supplies 32 and 44 supply appropriate high-frequency electric power to the lower electrode 30 and the upper electrode 40, respectively, producing a plasma containing radicals, ions, etc. between the lower electrode 30 and the upper electrode 40.

The portions of the face side 11a of the workpiece 11 that are not covered with the mask 25, i.e., the projected dicing lines 13, are exposed to the plasma, which processes the workpiece 11. The material gas for dry etching that is supplied from the gas supply source 42 may be a suitable gas selected depending on the material, etc. of the workpiece 11. When the workpiece 11 is thus dry-etched, etched grooves 19a are formed in the workpiece 11 to a depth which terminates short of, i.e., does not reach, the layered body 17. In other words, the etched grooves 19a are formed in the workpiece 11 in a manner to leave the layered body 17 unremoved therefrom.

FIG. 3A is a fragmentary side elevational view, partly in cross section, schematically showing the workpiece 11 with the etched grooves 19a formed therein in the dry etching step. In a dry etching process performed under such conditions which etch away appropriate portions of the workpiece 11, the layered body 17 that contains metal is usually essentially not removed. Therefore, even if the dry etching step is carried out for a relatively long period of time, the layered body 17 that is superposed on the projected dicing lines 13 will not be etched away.

In the dry etching step, inasmuch as the etched grooves 19a are formed by processing the workpiece 11 at once along all the projected dicing lines 13, the time required to process the workpiece 11 per projected dicing line 13 is shortened while keeping the quality of the processing of the workpiece 11, especially if the number of the projected dicing lines 13 on the workpiece 11 is large. After the dry etching step, the mask 25 is removed by ashing or the like.

After the dry etching step, the second holding step is carried out to hold the workpiece 11 on a chuck table (second holding table) of a cutting apparatus. FIG. 3B is a side elevational view, partly in cross section, illustrative of the second holding step. The second holding step is performed using a cutting apparatus 2 shown in FIG. 3B, for example. The cutting apparatus 2 includes a chuck table (second holding table) 4 for holding the workpiece 11 under suction thereon.

The chuck table 4 is coupled to a rotary actuator, not shown, such as a motor or the like, for rotation about an axis substantially parallel to a vertical direction. The chuck table 4 is disposed above a processing-feed mechanism, not shown, that moves the chuck table 4 in a processing-feed direction.

The chuck table 4 has an upper surface, part of which serves as a holding surface 4a for holding the workpiece 11, i.e., the dicing tape 21, under suction thereon. The holding surface 4a is connected to a suction source, not shown, through a suction channel, not shown, that is defined in the chuck table 4. When a negative pressure from the suction source is caused to act on the holding surface 4a, the workpiece 11 is held under suction on the chuck table 4. A plurality of clamps 6 for securing the annular frame 23 are provided on an outer peripheral region of the chuck table 4.

In the second holding step, the dicing tape 21 that sticks to the reverse side 11b of the workpiece 11 is held in contact with the holding surface 4a of the chuck table 4, and a negative pressure from the suction source is caused to act on the dicing tape 21. At the same time, the frame 23 is secured by the clamps 6. The workpiece 11 is thus securely held by the chuck table 4 and the clamps 6 with the layered body 17 on the face side 11a being exposed upwardly.

After the second holding step, the cutting step is carried out to cut the bottoms of the etched grooves 19a to sever the workpiece 11 and the layered body 17 along the projected dicing lines 13. FIG. 4 is a fragmentary side elevational view, partly in cross section, illustrative of the cutting step. The cutting step is performed also using the cutting apparatus 2. As shown in FIG. 4, the cutting apparatus 2 further includes a cutting unit 8 disposed above the chuck table 4.

The cutting unit 8 includes a spindle, not shown, that serves as a rotational shaft substantially perpendicular to the processing-feed direction. An annular cutting blade 10 made of a binder with abrasive grains dispersed therein is mounted on one end of the spindle. The other end of the spindle is coupled to a rotary actuator, not shown, such as a motor or the like. The cutting blade 10 on the one end of the spindle is rotatable about its own axis by forces transmitted from the rotary actuator. In the cutting step according to the present embodiment, the cutting blade 10 is of a thickness smaller than the width of the etched grooves 19a.

The spindle is supported by a moving mechanism, not shown, which moves the cutting blade 10 in an indexing-feed direction perpendicular to the processing-feed direction and a vertical direction perpendicular to the processing-feed direction and the indexing-feed direction. A pair of nozzles 12 are disposed on both sides of the cutting blade 10, which is thus disposed between the nozzles 12. The nozzles 12 are arranged to supply a cutting fluid 14 to the cutting blade 10 and the workpiece 11.

In the cutting step, the chuck table 4 is rotated about its own axis to bring a target etched groove 19a (projected dicing line 13) into alignment with the processing-feed direction of the cutting apparatus 2. The chuck table 4 and the cutting unit 8 are moved relatively to each other to position the plane of the cutting blade 10 into alignment with an extension of the target etched groove 19a (projected dicing line 13). Then, the lower end of the cutting blade 10 is moved to a position lower than the lower surface of the layered body 17.

Thereafter, while the cutting blade 10 is rotated about its own axis, the chuck table 4 is moved in the processing-feed direction. At the same time, the nozzles 12 supply the cutting fluid 14 which contains an organic acid and an oxidizing agent to the cutting blade 10 and the workpiece 11. The cutting blade 10 moves in and along the target etched groove 19a and cuts into the workpiece 11 and the layered body 17, fully severing the workpiece 11 and the layered body 17 thereby to form a kerf (slit) 19b in the layered body 17 along the target etched groove 19a.

The organic acid contained in the cutting fluid 14 modifies the metal in the layered body 17 to restrain its ductility. The oxidizing agent contained in the cutting fluid 14 makes it easier for the metal in the layered bodies 17 to be oxidized on its surface. As a result, the ductility of the metal in the layered body 17 is sufficiently lowered for increased processability of the workpiece 11.

As the organic acid included in the cutting fluid 14, there can be used, for example, a compound that has at least one carboxyl group and at least one amino group in its molecule. In this case, it is preferable that at least one of amino group(s) is a secondary or tertiary amino group. In addition, compound used as the organic acid may have a substituent group.

As the organic acid, there can be used amino acids. Examples of the amino acids usable here include glycine, dihydroxyethylglycine, glycylglycine, hydroxyethylglycine, N-methylglycine, β-alanine, L-alanine, L-2-aminobutyric acid, L-norvaline, L-valine, L-leucine, L-norleucine, L-alloisoleucine, L-isoleucine, L-phenylalanine, L-proline, sarcosine, L-ornithine, L-lysine, taurine, L-serine, L-threonine, L-allothreonine, L-homoserine, L-thyroxine, L-tyrosine, 3,5-diiodo-L-tyrosine, β-(3,4-dihydroxyphenyl)-L-alanine, 4-hydroxy-L-proline, L-cysteine, L-methionine, L-ethionine, L-lanthionine, L-cystathionine, L-cystine, L-cystic acid, L-glutamic acid, L-aspartic acid, S-(carboxymethyl)-L-cysteine, 4-aminobutyric acid, L-asparagine, L-glutamine, azaserine, L-canavanine, L-citrulline, L-arginine, δ-hydroxy-L-lysine, creatine, L-kynurenine, L-histidine, 1-methyl-L-histidine, 3-methyl-L-histidine, L-tryptophane, actinomycin C1, ergothioneine, apamin, angiotensin I, angiotensin II, antipain, etc. Among others, particularly preferred are glycine, L-alanine, L-proline, L-histidine, L-lysine, and dihydroxyethylglycine.

Also, amino polyacids can be used as the organic acid. Examples of the amino polyacids usable here include iminodiacetic acid, nitrilotriacetic acid, diethylenetriaminepentaacetic acid, ethylenediaminetetraacetic acid, hydroxyethyliminodiacetic acid, nitrilotrismethylenephosphonic acid, ethylenediamine-N,N,N′,N′-tetramethylenesulfonic acid, 1,2-diaminopropanetetraacetic acid, glycol ether diaminetetraacetic acid, transcyclohexanediaminetetraacetic acid, ethylenediamineorthohydroxyphenylacetic acid, ethylenediaminedisuccinic acid (SS isomer), β-alaninediacetic acid, N-(2-carboxylatoethyl)-L-aspartic acid, N—N′-bis(2-hydroxybenzyl)ethylenediamine-N,N′-diacetic acid, etc.

Further, carboxylic acids can be used as the organic acid. Examples of the carboxylic acids usable here include saturated carboxylic acids such as formic acid, glycolic acid, propionic acid, acetic acid, butyric acid, valeric acid, hexanoic acid, oxalic acid, malonic acid, glutaric acid, adipic acid, malic acid, succinic acid, pimelic acid, mercaptoacetic acid, glyoxylic acid, chloroacetic acid, pyruvic acid, acetoacetic acid, etc., unsaturated carboxylic acids such as acrylic acid, methacrylic acid, crotonic acid, fumaric acid, maleic acid, mesaconic acid, citraconic acid, aconitic acid, etc., and cyclic unsaturated carboxylic acids such as benzoic acids, toluic acid, phthalic acids, naphthoic acids, pyromellitic acid, naphthalic acid, etc.

As the oxidizing agent included in the cutting fluid 14, there can be used, for example, hydrogen peroxide, peroxides, nitrates, iodates, periodates, hypochlorites, chlorites, chlorates, perchlorates, persulfates, dichromates, permanganates, cerates, vanadates, ozonated water, silver(II) salts, iron(III) salts, and their organic complex salts.

Besides, an anticorrosive may be mixed in the cutting fluid 14. Mixing of the anticorrosive makes it possible to prevent corrosion (elution) of the metal included in the workpiece 11. As the anticorrosive, there is preferably used a heterocyclic aromatic ring compound which has at least three nitrogen atoms in its molecule and has a fused ring structure or a heterocyclic aromatic ring compound which has at least four nitrogen atoms in its molecule. Further, the aromatic ring compound preferably includes a carboxyl group, sulfo group, hydroxyl group, or alkoxyl group. Specific preferable examples of the aromatic ring compound include tetrazole derivatives, 1,2,3-triazole derivatives, and 1,2,4-triazole derivatives.

Examples of the tetrazole derivatives usable as the anticorrosive include those which do not have a substituent group on the nitrogen atoms forming the tetrazole ring and which have, introduced into the 5-position of the tetrazole, a substituent group selected from the group consisting of sulfo group, amino group, carbamoyl group, carbonamide group, sulfamoyl group, and sulfonamide group, or an alkyl group substituted with at least one substituent group selected from the group consisting of hydroxyl group, carboxyl group, sulfo group, amino group, carbamoyl group, carbonamide group, sulfamoyl group, and sulfonamide group.

Examples of the 1,2,3-triazole derivatives usable as the anticorrosive include those which do not have a substituent group on the nitrogen atoms forming the 1,2,3-triazole ring and which have, introduced into the 4-position and/or 5-position of the 1,2,3-triazole, a substituent group selected from the group consisting of hydroxyl group, carboxyl group, sulfo group, amino group, carbamoyl group, carbonamide group, sulfamoyl group, and sulfonamide group, or an alkyl or aryl group substituted with at least one substituent group selected from the group consisting of hydroxyl group, carboxyl group, sulfo group, amino group, carbamoyl group, carbonamide group, sulfamoyl group, and sulfonamide group.

Besides, examples of the 1,2,4-triazole derivatives usable as the anticorrosive include those which do not have a substituent group on the nitrogen atoms forming the 1,2,4-triazole ring and which have, introduced into the 2-position and/or 5-position of 1,2,4-triazole, a substituent group selected from the group consisting of sulfo group, carbamoyl group, carbonamide group, sulfamoyl group, and sulfonamide group, or an alkyl or aryl group substituted with at least one substituent group selected from the group consisting of hydroxyl group, carboxyl group, sulfo group, amino group, carbamoyl group, carbonamide group, sulfamoyl group, and sulfonamide group.

The above process is repeated to cut to form kerfs 11b along all the etched grooves 19a (projected dicing lines 13), whereupon the cutting step is finished. According to the present embodiment, as described above, the cutting fluid 14 which contains an organic acid and an oxidizing agent is supplied to the workpiece 11 in severing the layered bodies 17 that contain metal with the cutting blade 10. The organic acid and the oxidizing agent are effective to modify the metal contained in the layered bodies 17, thereby lowering the ductility of the metal while the cutting blade 10 is severing the layered bodies 17. The metal is thus prevented from forming burrs even when the workpiece 11 is processed at an increased rate.

According to the present embodiment, since the cutting blade 10 that has a thickness smaller than the width of the etched grooves 19a is used, the cutting fluid 14 tends to accumulate between the side wall surfaces of the etched groove 19a and the cutting blade 10. As a consequence, the layered body 17 can be supplied with a sufficient amount of cutting fluid 14 for further increased processability of the workpiece 11.

In the workpiece processing method according to the present embodiment, as described above, the cutting fluid 14 which contains an organic acid and an oxidizing agent is supplied to the cutting blade 10 and the workpiece 11 in severing the layered body 17 containing metal with the cutting blade 10. The organic acid and the oxidizing agent are effective to modify the metal contained in the layered body 17, thereby lowering the ductility of the metal while the cutting blade 10 is severing the layered body 17. The metal is thus prevented from forming burrs even when the workpiece 11 is processed at an increased rate. In other words, the rate at which the workpiece 11 is processed can be increased while keeping the quality of the processing of the workpiece 11.

In the workpiece processing method according to the present embodiment, inasmuch as dry etching is performed on the workpiece 11 through the mask 25 provided in the areas exclusive of the projected dicing lines 13, processing the workpiece 11 at once along all the projected dicing lines 13 to form the etched grooves 19a therein, the time required to process the workpiece 11 per projected dicing line 13 is shortened while keeping the quality of the processing of the workpiece 11, especially if the number of the projected dicing lines 13 on the workpiece 11 is large. In other words, the rate at which the workpiece 11 is processed can be increased while keeping the quality of the processing of the workpiece 11.

The present invention is not limited to the above embodiment, but various changes and modifications may be made therein. For example, while the workpiece 11 in which the layered body 17 containing metal is formed on the reverse side 11b thereof is processed in the above embodiment, a workpiece in which a layered body containing metal is formed on the face side thereof may be processed. Such a workpiece may be a wafer or the like in which layered bodies including evaluation elements referred to as TEG (Test Element Group) or the like are provided in respective positions superposed on projected dicing lines on a face side of the wafer or the like.

In the above embodiment, the cutting blade 10 cuts into the workpiece 11 from the face side 11a thereof. However, the cutting blade 10 may cut into the workpiece 11 from the reverse side 11b thereof. In such a modification, it is necessary to peel off the dicing tape 21 and then hold the face side 11a of the workpiece 11 on the chuck table 4 with the reverse side 11b of the workpiece 11 being exposed upwardly.

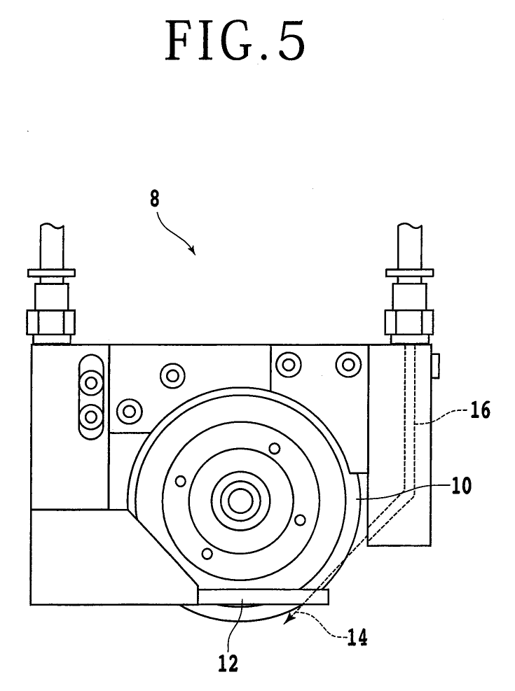

In the above cutting step, the cutting fluid 14 is supplied from the nozzles 12 disposed on both sides of the cutting blade 10. However, the present invention is not limited to any particular nozzle configuration for supplying the cutting fluid 14. FIG. 5 is a side elevational view of a nozzle for supplying the cutting fluid 14 according to another mode of the present invention. As shown in FIG. 5, a cutting unit 8 as a modification, includes, in addition to the cutting blade 10 and the pair of nozzles 12, a shower nozzle 16 disposed in front of or behind the cutting blade 10.

The nozzle 16 makes it easier to supply the cutting fluid 14 to the kerf (slit) 19b for more effectively modifying the metal contained in the layered body 17. In particular, the nozzle 16 has an ejection port oriented obliquely downwardly toward a region where the cutting blade 10 processes the workpiece 11, as shown in FIG. 5, so that the kerf 19b is supplied and filled with an increased amount of cutting fluid 14 for more effectively modifying the metal contained in the layered body 17. Though both the nozzles 12 and the nozzle 16 are used in FIG. 5, the nozzles 12 may be dispensed with and only the nozzle 16 may be used alone.

The present invention is not limited to the details of the above described preferred embodiment. The scope of the invention is defined by the appended claim and all changes and modifications as fall within the equivalence of the scope of the claim are therefore to be embraced by the invention.

What is claimed is:

1. A method of processing a plate-shaped workpiece that includes a layered body containing metal which is formed in superposed relation to projected dicing lines, comprising the steps of:
holding a layered body side of said workpiece on a first holding table;
thereafter, performing dry etching on said workpiece through a mask disposed in areas that are exclusive of said projected dicing lines thereby to form etched grooves in said workpiece along said projected dicing lines in a manner to leave said layered body unremoved;
thereafter, holding the layered body side of said workpiece or a side of said workpiece which is opposite the layered body side thereof on a second holding table; and
thereafter, cutting bottoms of said etched grooves with a cutting blade to sever said workpiece and said layered body along said projected dicing lines;
wherein the step of cutting the bottoms of said etched grooves includes the step of cutting the bottoms of said etched grooves while supplying a cutting fluid containing an organic acid and an oxidizing agent to said workpiece.

2. The method according to claim 1, wherein said cutting blade has a thickness smaller than the width of said etched grooves.
